(19) United States
(12) Patent Application Publication
(10) Pub. No.: US 2003/0234372 A1
(43) Pub. Date: Dec. 25, 2003

(54) Ion source of an ion implantation apparatus

(76) Inventor: Sang-Kuk Park, Yongin-si (KR)

Correspondence Address: VOLENTINE FRANCOS, P.L.L.C., Suite 150, 12200 Sunrise Valley Drive, Reston, VA, 20191, US

(21) Appl. No.: 10/436,974

(22) Filed: May 14, 2003

(30) Foreign Application Priority Data
Jun. 20, 2002 (KR) 2002-34584

(51) Int. Cl. H01J 37/30; H01J 37/08

(52) U.S. Cl. 250/492.21; 250/426; 315/111.81

(57) ABSTRACT

An ion source for ionizing reactant gases in an ion implantation process for manufacturing semiconductor devices includes an arc chamber into which gas is supplied through a gas line, and a spray nozzle that is connected with the gas line. The spray nozzle has a plurality f minute spray openings that spray the gas flowing through the gas line uniformly into the arc chamber at a high velocity.

### BACKGROUND OF THE INVENTION

1. Field of the Invention

The present invention relates to an ion implantation apparatus used in fabricating semiconductor devices. More particularly, the present invention relates to an ion source of an ion implantation apparatus.

2. Description of the Related Art

One of the basic techniques in the fabricating of semiconductor devices is an ion implantation process of implanting impurities in a silicon substrate. In particular, the ion implantation process collide ions having high energy with the substrate, thereby physically filling the substrate with the ions. An ion implantation apparatus used for performing the ion implantation process comprises an ion source for generating the ions to be implanted into the substrate.

Generally, as shown in FIG. 1, the ion source comprises an arc chamber 12 in which the ions are generated. A filament 14 through which electric current flows is disposed within the arc chamber 12. A reflector 16 is located on a side of the chamber 12 opposite the filament 12 and negative electric current flows through the reflector 16. An inlet port 18 extends through a tungsten base plate 13 of the arc chamber 12, and a gas supply pipe 20 for supplying source gases into the arc chamber 12 is connected to the inlet port 18. As is also shown FIG. 1, the inlet port 18 consists of one large opening having a diameter of about 10 mm. Therefore, various problems occur.

First, the mobility of the gas molecules is poor because the gases can only be supplied into the arc chamber 12 through the large opening of the inlet port 18 at a relatively small velocity. This, in turn, leads to a low probability of reactant gases colliding with thermal electrons emitted from the filament 12.

Second, the gases are not supplied uniformly in the arc chamber 12 and concentrate in front of the inlet port 18, as shown at FIG. 1. This prevents plasma from being formed. Accordingly, the ionization efficiency in the arc chamber 12 is low, meaning that a large amount of the gases is used during the implantation process.

Third, a large amount of residual substances is deposited on the base plate 13 and, in particular, on the gas inlet port 18 during the ionization of the source gas because the base plate is made of tungsten. As the ionization process proceeds, the amount of deposition is increased. Finally, the opening of the inlet port 18 is gradually choked and the gases are not smoothly supplied into the arc chamber 12.

### SUMMARY OF THE INVENTION

An object of the present invention to provide an ion source of an ion implantation apparatus, that performs with a high degree of ionization efficiency.

It is another object of the present invention to provide an ion source of an ion implantation apparatus, that use a relatively small amount of gas to produce an ion beam.

It is still another object of the present invention to provide an ion source of an ion implantation apparatus, that uniformly supplies the gases into an arc chamber thereof.

In accordance with an aspect of the present invention, an ion source comprises an arc chamber having a gas line through which the gases are supplied, a first electrode installed on an inner wall of the arc chamber, and a second electrode installed on an inner wall of the arc chamber opposite the first electrode. A spray nozzle is connected with the gas line and has a plurality of minute holes so that the gases are uniformly sprayed toward the arc chamber at a high velocity.

According to another aspect of the present invention, the spray nozzle is made of boron nitride or ceramic to prevent residual substances from being deposited thereon in the arc chamber.

### BRIEF DESCRIPTION OF THE DRAWINGS

Additional objects, features and advantages of the present invention will be more readily apparent from the following detailed description of preferred embodiments thereof when taken together with the accompanying drawings in which:

FIG. 1 is a schematic view of a conventional ion source of an ion implantation apparatus;

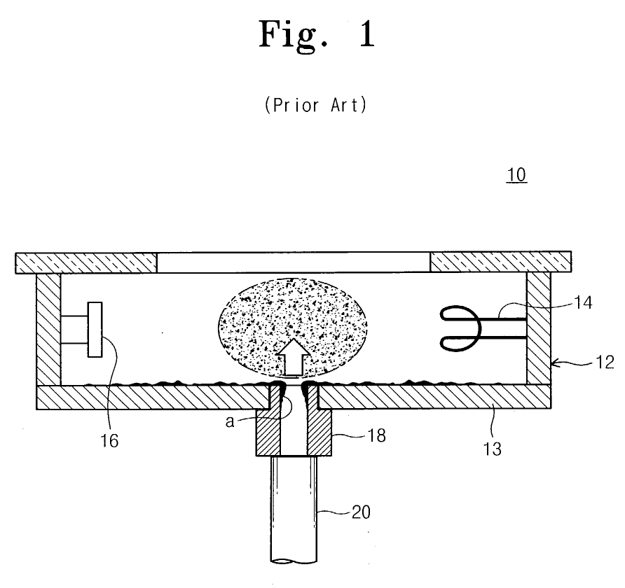

FIG. 2 is a schematic view of an ion implantation apparatus comprising an ion source according to an embodiment of the present invention;

FIG. 3 is a sectional view of the ion source shown in FIG. 2;

FIG. 4 is a perspective view of a spray nozzle of the ion source shown in FIG. 3;

FIG. 5 is a sectional view of an ion source according to another embodiment of the present invention; and

FIG. 6 is a perspective view of the base plate of the ion source shown in FIG. 5.

### DETAILED DESCRIPTION OF THE PREFERRED EMBODIMENTS

The present invention will now be described more fully hereinafter with reference to the attached figures.

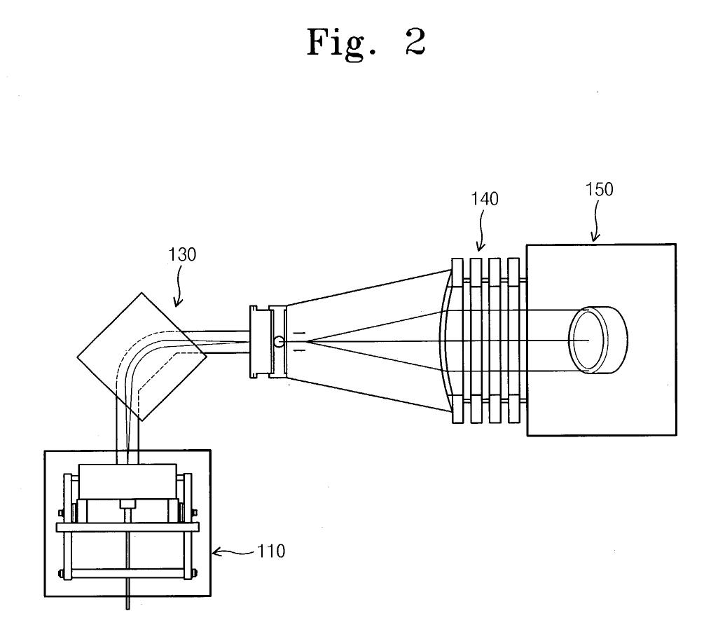

Referring to FIG. 2, the ion implantation apparatus includes an ion source 110 for forming an ion beam by ionizing reactant gases, an analyzer 130 for removing undesired impurities from the ion beam, an accelerator 140 for accelerating the ion beam with energy in a range of 2 KeV to 200 KeV, and an ion implantation chamber 150.

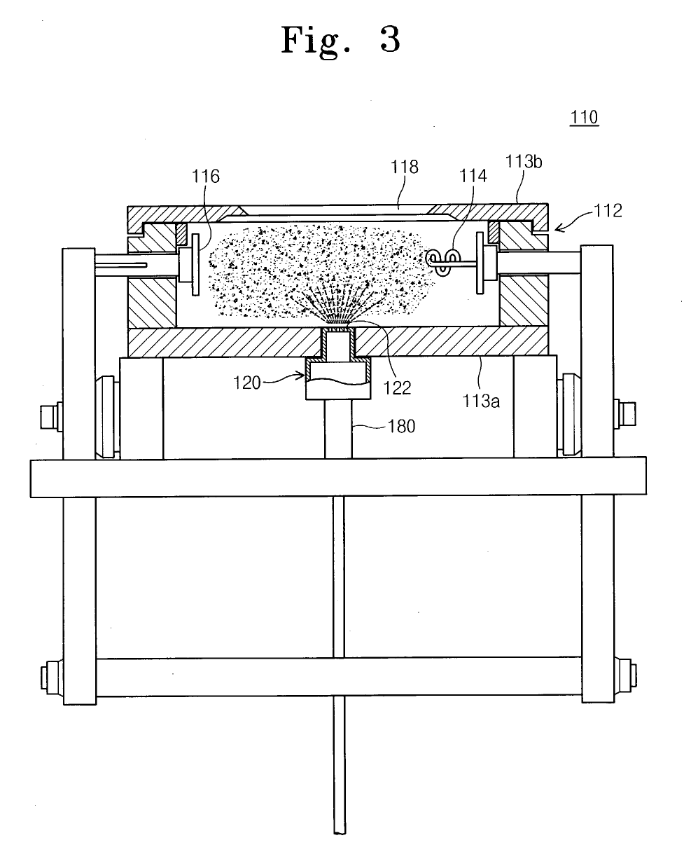

Referring to FIG. 3, the ion source 110 has an arc chamber 112 in which the reactant gases are ionized. A filament 114 is installed on an inner wall of the arc chamber 112 and thermal electrons which provide the bases for generating ions is emitted from the filament 114. The filament 114 is connected with a source of external power (not shown). A reflector 116 is installed on the inner wall of the arc chamber 112 opposite the filament and negative current flows through the reflector 116. A gas spray nozzle 120 is installed on a base plate 113a of the arc chamber 112. An exit aperture 118 for the ion beam is formed in a front plate 113b of the arc chamber 112 which is located opposite the base plate 113a.

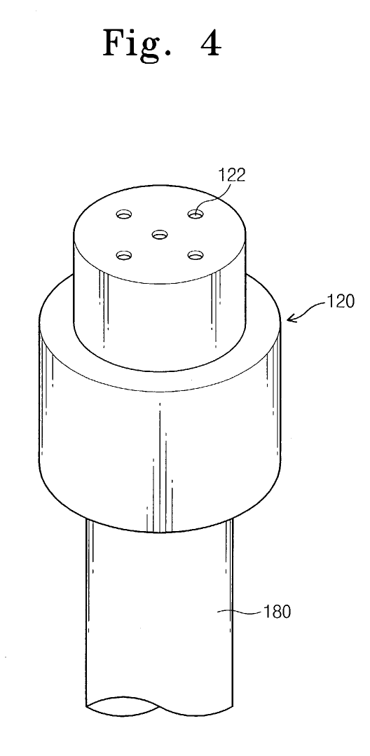

The gas spray nozzle 120 is connected with a gas line 180. Referring to FIG. 4, the gas spray nozzle 120 has a plurality of minute spray holes (about 0.5 mm in diameter) so that reactant gases are uniformly sprayed toward the inside of the arc chamber 112 at a high velocity. The reaction gases are supplied into the arc chamber 112 through the gas spray nozzle 120 from a gas source (not shown) and are ionized by thermal electrons emitted from the filament 114.

The reactant gases, including impurities such as arsenic (As), phosphorus (P), boron (B), and argon (Ar) are supplied to the inside of the arc chamber 112 from the gas source through the gas spray nozzle 120. Thermal electrons are emitted from the filament 114 when electric current flows therethrough. The thermal electrons collide with the reactant gases, thereby ionizing the reactant gases. The ionized reactant gas (or ion beam) is emitted from the arc chamber 112 through the exit aperture 118 of the arc chamber 112. The emitted ions are accelerated in the accelerator 140 so that the ions have a predetermined energy. Then the emitted ions are used in an ion implantation process.

The thermal electrons move toward the walls of the arc chamber 112 due to the electric potential difference between the arc chamber 112 and the filament 114. During this movement, the thermal electrons collide with the reactant gases and ionize them. The reactant gas flows in the arc chamber 112 with a high velocity because the reactant gas was forced through the minute holes of the gas spray nozzle 120. The reactant gas molecules have a great deal of mobility because the velocity of the reactant gas is relatively high. Therefore, the probability of the reactant gases and the thermal electrons colliding is correspondingly high. And, the ionization efficiency is also high because the reactant gases are supplied to the inside of the arc chamber 112 as a shower or spray.

Also, as was discussed above, a great amount of substances is deposited on the prior art base plate, in particular, on the inlet port, while the reactant gases are ionized because the conventional base plate is made of tungsten. On the other hand, the gas spray nozzle 120 of the present invention is made of boron nitride or ceramic to prevent the substances from being deposited on the inlet port. Accordingly, the gases are supplied smoothly in the ion source of the present invention without the inlet being chocked even over a long period of use.

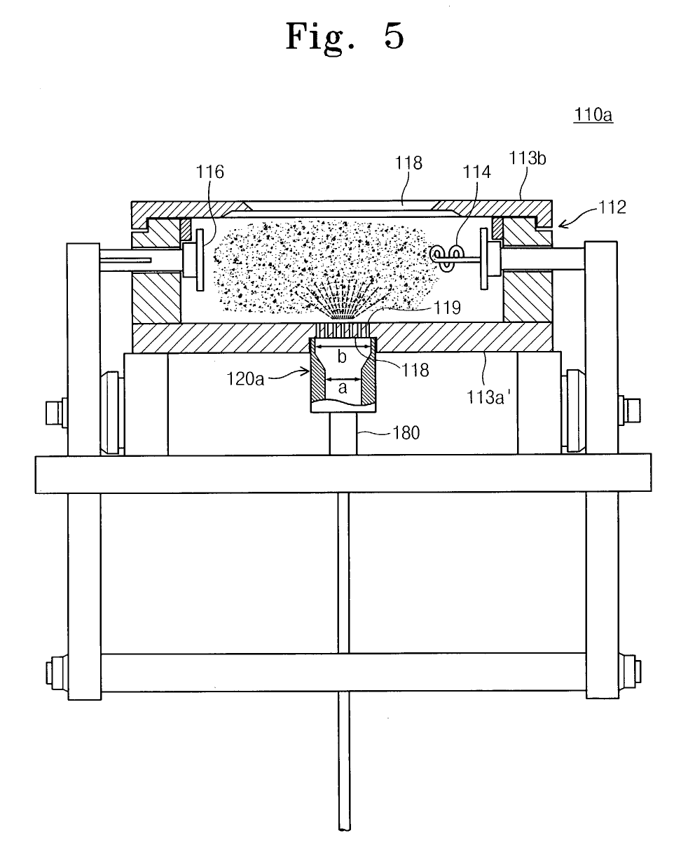

In FIG. 5, an ion source 110a includes the same components (i.e., an arc chamber 112a, a filament 114, and a reflector 116) as the ion source 110 shown in FIG. 3. These components have the same functions and construction as previously stated in FIG. 3, and will not be explained in further detail. Unlike the ion source 110 shown in FIG. 3, a base plate of the arc chamber 112a has spray holes 119.

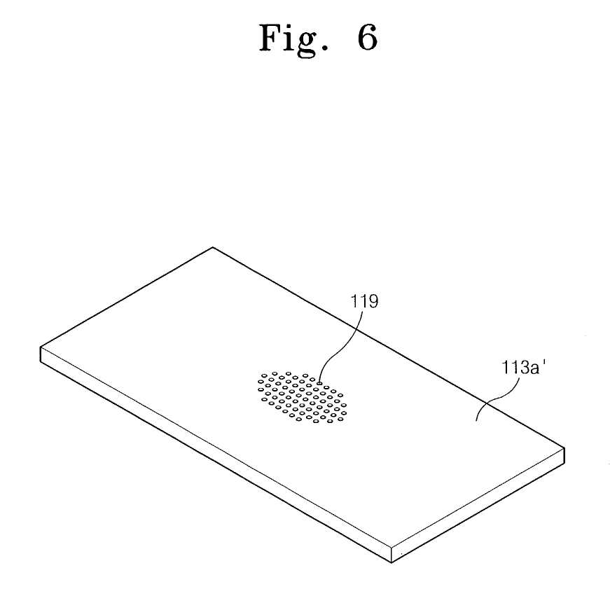

Referring to FIG. 5 and FIG. 6, the spray holes 119 are formed at a groove 118 of the base plate 113a′. In view of the beam slit shape, the spray holes 119 are wholly elliptical. A spray nozzle 120a may be weld-connected with the groove 118 formed at a bottom side of the base plate 113a. The spray nozzle 120a serves to connect a gas line 180 with the spray holes 119 formed at the base plate 113a′. The width “b” of a gas-outlet port of the spray nozzle 120a is greater than the width “a” of a gas-inlet port connected to the gas line 180.

For example, gas supplied through the gas line 180 passes the spray nozzle 120a to be uniformly sprayed to the inside of the arc chamber 112a through the spray holes 119 formed at the base plate 113a′. As a result, it is possible to obtain the same effect as described in the foregoing embodiment. The base plate is made of, for example, tungsten (W).

Finally, although the present invention has been shown and described with respect to the preferred embodiment thereof, the present invention is not so limited. Rather, various modifications and changes may be made thereto without departing from the true spirit and scope of the invention as defined by the appended claims.

What is claimed is:

1. An ion source of an ion implanter, comprising:
an arc chamber;
a gas line through which gases are supplied;
a first electrode disposed on an inner wall of the arc chamber;
a second electrode disposed on an inner wall of the arc chamber opposite the first electrode; and
a spray nozzle connected to the gas line, the spray nozzle having a plurality of discrete spray openings facing the interior of the arc chamber, whereby gas flowing through the gas line can be sprayed into the arc chamber uniformly at a high velocity.

2. The ion source of claim 1, wherein the spray nozzle is made of boron nitride.

3. The ion source of claim 1, wherein the spray nozzle is made of ceramics.

4. The ion source of claim 1, wherein the arc chamber further comprises a first plate through which the spray nozzle extends and a second plate having an exit aperture through which an ion beam produced in the chamber exits the chamber, the second plate being disposed opposite the first plate.

5. The ion source of claim 1, wherein each of the spray openings has a diameter of about 0.5 mm.

6. An ion implantation apparatus comprising:
an ion source including an arc chamber having an ion beam exit aperture, a gas line through which gases are supplied, a first electrode disposed on an inner wall of the arc chamber, a second electrode disposed on an inner wall of the arc chamber opposite the first electrode, and a spray nozzle connected to the gas line, the spray nozzle having a plurality of discrete spray openings facing the interior of the arc chamber, whereby gas flowing through the gas line can be sprayed into the arc chamber uniformly at a high velocity whereupon molecules of the gas collide with electrons emitted by the first electrode, thereby creating an ion beam that is emitted through the exit aperture;
an analyzer connected to the aperture of the ion source so as to remove undesired impurities from the ion beam;
an accelerator that accelerates the ion beam; and
an ion implantation chamber connected to the accelerator and disposed at a downstream end of the apparatus such that the ion beam accelerated by the accelerator is directed into the ion implantation chamber.

7. The ion implantation apparatus of claim 6, wherein the spray nozzle of the ion source is made of boron nitride.

8. The ion implantation apparatus of claim 6, wherein the spray nozzle of the ion source is made of ceramics.

9. The ion implantation apparatus of claim 6, wherein the arc chamber of the ion source further comprises a first plate through which the spray nozzle extends and a second plate through which the exit aperture extends, the second plate being disposed opposite the first plate.

10. The ion implantation apparatus of claim 6, wherein each of the spray openings of the spray nozzle of the ion source has a diameter of about 0.5 mm.

11. An ion source of an ion implanting apparatus, comprising:
an arc chamber receiving gas through a gas line;
a first electrode disposed at the arc chamber; and
a second electrode disposed to be opposite to the first electrode,
wherein the arc chamber includes a first plate having a plurality of spray holes so as to enhance the spray velocity of the gas supplied through the gas line and uniformly spray the gas to the inside of the arc chamber.

12. The ion source of claim 11, further comprising a spray nozzle installed at the base plate so as to supply the gas supplied through the gas line to the spray holes,
wherein the base plate has a groove to which the spray nozzle is connected and the spray holes are formed at the groove of the plate.

13. The ion source of claim 11, wherein the spray holes are wholly elliptical in view of the beam slit shape.

14. The ion source of claim 11, wherein a gas-outlet port of the spray nozzle is wider than a gas-inlet port thereof.
